(19) United States
(12) Patent Application Publication
(10) Pub. No.: US 2025/0241027 A1
(43) Pub. Date: Jul. 24, 2025

(54) SEMICONDUCTOR DEVICE

(71) Applicant: UNITED MICROELECTRONICS CORP., Hsin-Chu City (TW)

(72) Inventors: Chih-Yi Wang, Tainan City (TW); Hung-Chun Lee, Pingtung County (TW); Wei-Hao Chang, Taichung City (TW); Wei-Che Chen, Kaohsiung City (TW); Kun-Szu Tseng, Tainan City (TW); Yao-Jhan Wang, Tainan City (TW)

(73) Assignee: UNITED MICROELECTRONICS CORP., Hsin-Chu City (TW)

(21) Appl. No.: 18/586,569

(22) Filed: Feb. 26, 2024

(30) Foreign Application Priority Data
Jan. 22, 2024 (TW) 113102437

(51) Int. Cl. H01L 29/06; H01L 27/088; H01L 29/66; H01L 29/78

(52) U.S. Cl. CPC H10D 62/117; H10D 30/024; H10D 30/62; H10D 84/834

(57) ABSTRACT

A semiconductor device includes a substrate having a first planar region, a second planar region adjacent to the first planar region, a non-planar region between the first planar region and the second planar region, a first base on the first planar region, a second base on the second planar region, and a plurality of bumps on the non-planar region. Preferably, the bumps have different heights, top surfaces of the first base and the second base are coplanar, the top surface of the bumps is lower than the top surface of the first base, and the height of the bumps closer to the first planar region is greater than the height of the bumps closer to the non-planar region.

### BACKGROUND OF THE INVENTION

### 1. Field of the Invention

The invention relates to a semiconductor device, and more particularly to a semiconductor device having bumps of different heights adjacent to a planar region.

### 2. Description of the Prior Art

In current semiconductor processing, controllers, memories, circuits of low-voltage operation and power devices of high-voltage operation are largely integrated into a single chip to achieve a single-chip system. The power device or high-voltage (HV) device, such as vertical double-diffusion metal-oxide-semiconductor (VDMOS), insulated gate bipolar transistor (IGBT) and lateral diffusion MOS (LDMOS), is employed to increase power switching efficiency and decrease the loss of energy resources. It is often required that the switching transistors withstand high breakdown voltages and operate at a low on-resistance.

Moreover with the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the fin FET can be controlled by adjusting the work function of the gate.

However as the scale of current devices continue to decrease the integration of high-voltage devices and FinFET devices start to face numerous challenges such as current leakage and control of breakdown voltage. Hence, how to improve the current fabrication for improving performance of the device has become an important task in this field.

### SUMMARY OF THE INVENTION

According to an embodiment of the present invention, a semiconductor device includes a substrate having a first planar region, a second planar region adjacent to the first planar region, a non-planar region between the first planar region and the second planar region, a first base on the first planar region, a second base on the second planar region, and a plurality of bumps on the non-planar region. Preferably, the bumps have different heights, top surfaces of the first base and the second base are coplanar, the top surface of the bumps is lower than the top surface of the first base, and the height of the bumps closer to the first planar region is greater than the height of the bumps closer to the non-planar region.

According to another aspect of the present invention, a semiconductor device includes a substrate having a planar region and non-planar region, bumps in the non-planar region, and dummy fin-shaped structures in the non-planar region and adjacent to the bumps.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating a semiconductor device according to an embodiment of the present invention.

FIGS. 5-11 illustrate a method for fabricating a semiconductor device according to an embodiment of the present invention.

### DETAILED DESCRIPTION

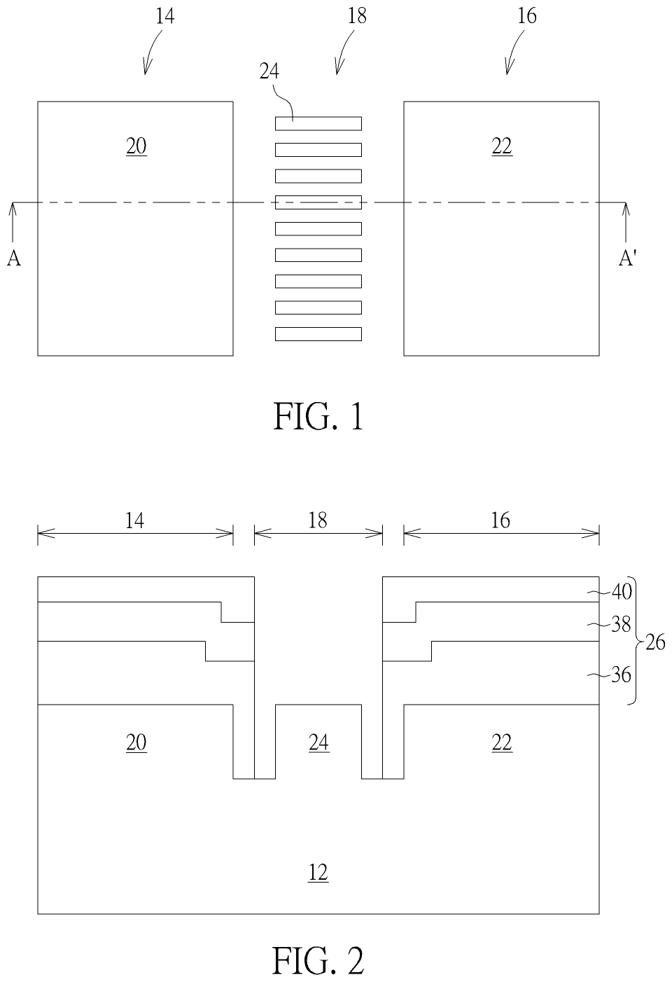

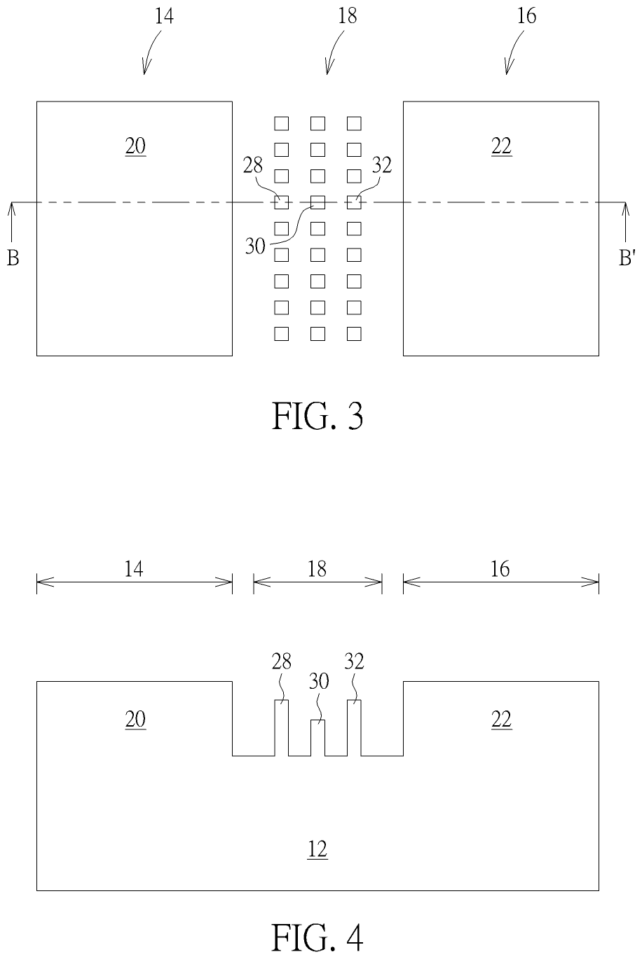

Referring to FIGS. 1-4, FIGS. 1 and 3 illustrate top views for fabricating a semiconductor device according to an embodiment of the present invention, FIG. 2 illustrates a method for fabricating the semiconductor device taken along the sectional line AA′ shown in FIG. 1, and FIG. 4 illustrates a method for fabricating the semiconductor device taken along the sectional line BB′ shown in FIG. 3. As shown in FIGS. 1-2, a substrate 12, such as a silicon substrate or silicon-on-insulator (SOI) substrate is provided and two planar regions 14, 16 and a non-planar region 18 between the planar regions 14, 16 are defined on the substrate 12, in which planar devices such as HV devices and medium-voltage (MV) devices could be formed on the planar regions 14, 16 and non-planar structures such as fin-shaped structures used for improving overall balance of the device could be formed on the non-planar region 18 in the later process.

Next, bases 20, 22 are formed on the substrate 12 of the planar regions 14, 16 respectively and a plurality of fin-shaped structures 24 are formed on the substrate 12 of the non-planar region 18. Preferably, the bases 20, 22 and/or the fin-shaped structures 24 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate 12 underneath.

Alternatively, the bases 20, 22 and/or the fin-shaped structures 24 could also be obtained by first forming a patterned mask (not shown) on the substrate, 12, and through an etching process, the pattern of the patterned mask is transferred to the substrate 12 to form the bases 20, 22 and/or the fin-shaped structures 24. Moreover, the formation of the bases 20, 22 and/or the fin-shaped structures 24 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding the bases 20, 22 and/or fin-shaped structures 24. These approaches for forming the bases 20, 22 and/or fin-shaped structures 24 are all within the scope of the present invention. Since the bases 20, 22 and the fin-shaped structures 24 are all formed through same process, the top surfaces of the bases 20, 22 and fin-shaped structures 24 are coplanar.

It should be noted that after the bases 20, 22 and the fin-shaped structures 24 are formed, each of the bases 20, 22 having rectangular shape from a top view perspective is disposed on the two planar regions 14, 16 respectively while the fin-shaped structures 24 having rectangular stripe shape from top view perspective are extending along the X-direction between the two planar regions 14, 16 in the non-planar region 18. Next, a patterned mask 26 is formed on the planar regions 14, 16, in which the patterned mask 26 includes an opening exposing all of the fin-shaped structures 24 on the non-planar region 18. In this embodiment, the patterned mask 26 could be a multilayer mask made of an organic dielectric layer (ODL) 36, a silicon-containing hard mask bottom anti-reflective coating (SHB) 38, and a patterned resist 40.

Next, as shown in FIGS. 2-4, a fin cut process is conducted by using the patterned mask 26 as mask to remove part of the fin-shaped structures 24 between the planar regions 14, 16 in the non-planar region 18 through etching, and the patterned mask 26 is removed thereafter. It should be noted that since a height difference is typically observed between the patterned mask 26 closer to the non-planar region 18 and the patterned mask 26 farther away from the non-planar region 18 such that the top surface of the patterned mask 26 closer to the non-planar region 18 is slightly lower than the top surface of the patterned mask 26 away from the non-planar region 18, the etching process conducted by using the patterned mask 26 to remove the fin-shaped structures 24 on the non-planar region 18 would only remove a major portion of the fin-shaped structures 24 so that the remaining fin-shaped structures 24 would form bumps 28, 30, 32 having different heights on the substrate 12 of the non-planar region 18.

Specifically, each of the fin-shaped structures 24 extending along X-direction on the non-planar region 18 after being etched through fin cut process would be formed into a plurality of bumps such as three bumps 28, 30, 32 extending along X-direction or Y-direction. Preferably, the top surfaces of all the bumps 28, 30, 32 are slightly lower than the top surface of the bases 20, 22 disposed on two adjacent planar regions 14, 16. For instance, the height of each of the bumps 28, 30, 32 could be less than ½, ⅓, ¼, or even ⅕ of the overall height of each of the bases 20, 22. Moreover, the height of the bumps 28, 32 closer to the planar regions 14, 16 is slightly greater than the height of bump 30 closer to the non-planar region 18, or more specifically the height of the bumps 28, 32 closer to the planar regions 14, 16 is greater than the height of the bump 30 on the center or middle of the non-planar region 18.

Taking the three bumps 28, 30, 32 on the non-planar region 18 as an example, the height of the bump 28 closer to the left planar region 14 and the height of the bump 32 closer to the right planar region 16 are both greater than the height of the bump 30 closer to the non-planar region 18 (or the bump 30 in the center of the non-planar region 18 between two planar regions 14, 16) while the height of the bump 28 closer to the left planar region 14 could be equal to the height of the bump 32 closer to the right planar region 16. In other words, the three bumps 28, 30, 32 disposed on the non-planar region 18 have two different heights, in which the height of the bump 28 closer to the left planar region 14 and the height of the bump 32 closer to the right planar region 16 are both greater than the height of the bump 30 in the center of the non-planar region 18.

It should be noted that even though the aforementioned embodiment pertains to disposing three bumps 28, 30, 32 on the non-planar region 18, according to other embodiment of the present invention, each of the fin-shaped structures 24 on the non-planar region 18 after being etched and patterned by fin cut process could be formed into multiple bumps such as more than three bumps, four bumps, five bumps or even six bumps or greater, in which the heights of the bumps closer to the planar region 14, 16 on two adjacent sides are greater than the heights of the bumps closer to the middle of the non-planar region 18. For instance, if four bumps were formed on the non-planar region 18, the heights of the two bumps closer to the planar regions 14, 16 on two adjacent sides could be greater than the heights of the two bumps closer to the middle of the non-planar region 18. If five bumps were formed on the non-planar region 18, the heights of the two bumps closer to the planar regions 14, 16 could be greater than the heights of the three bumps closer to the middle of the non-planar region 18 or the heights of the four bumps closer to the planar regions 14, 16 could be greater than the height of the single bump closer to the middle of the non-planar region 18, which are all within the scope of the present invention.

It should also be noted that even though two planar regions 14, 16 and a single non-planar region 18 between the planar regions 14, 16 are disposed on the substrate 12 in this embodiment, according to other embodiment of the present invention, it would also be desirable to only form a single planar region and a single non-planar region adjacent to the planar region, in which a single base is disposed on the planar region, a plurality of bumps having different heights are disposed on the non-planar region, and the height of the bumps closer to the planar region is slightly greater than the height of the bumps closer to the non-planar region, which is also within the scope of the present invention.

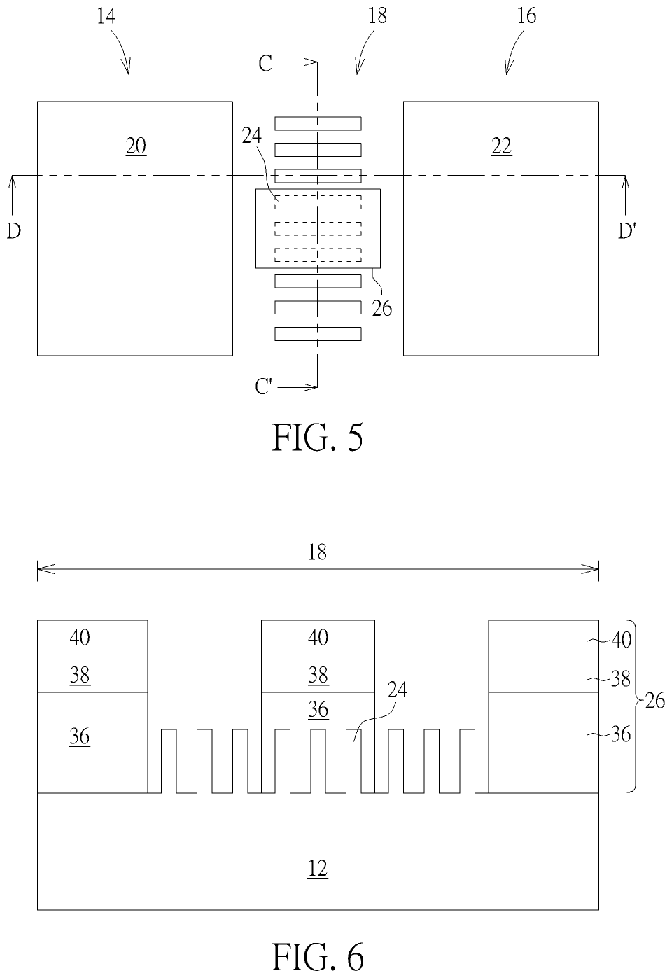

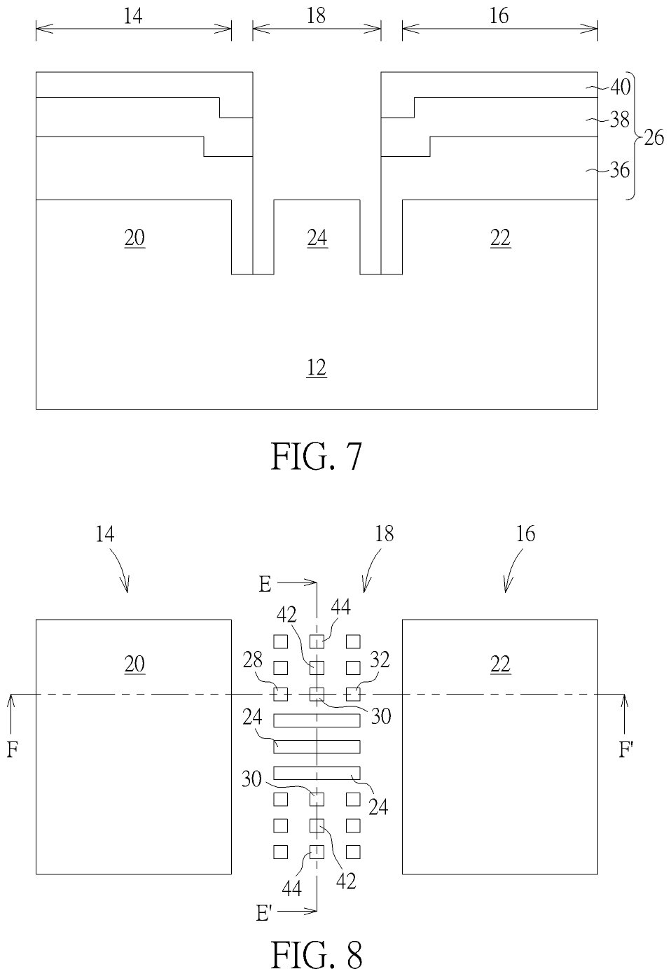

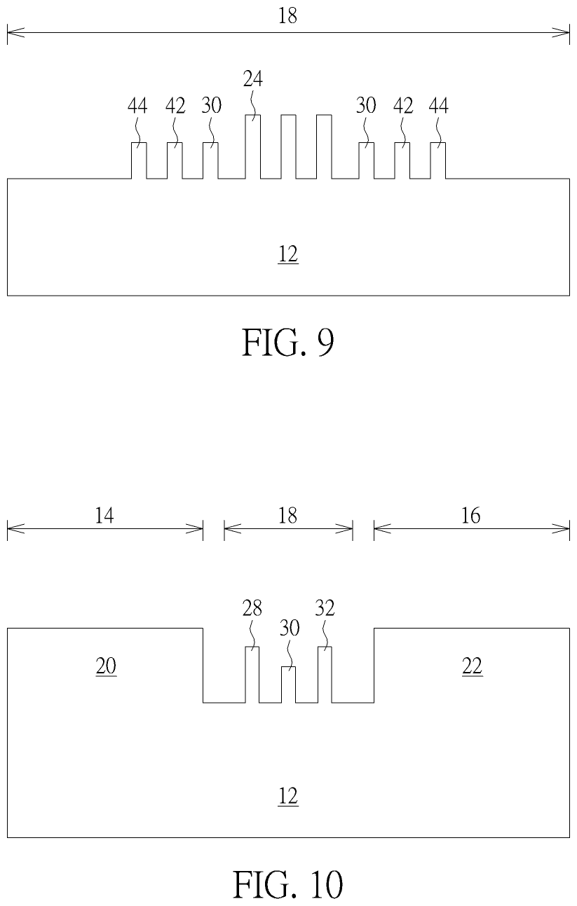

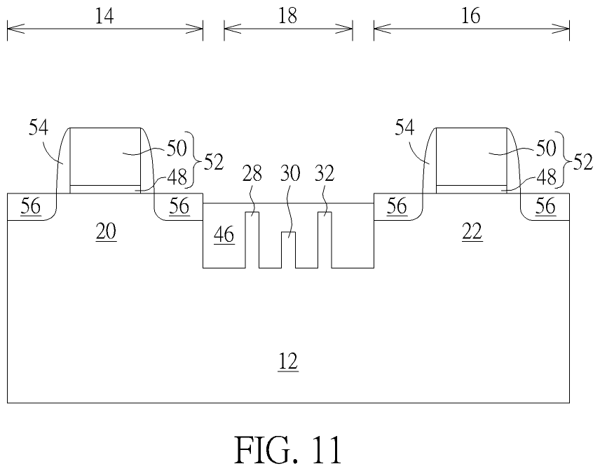

Referring to FIGS. 5-11, FIGS. 5-11 illustrate a method for fabricating a semiconductor device according to an embodiment of the present invention, in which FIGS. 4 and 8 illustrate top views for fabricating the semiconductor device according to an embodiment of the present invention, FIG. 6 illustrates a cross-section view for fabricating the semiconductor device taken along the sectional line CC′ shown in FIG. 5, FIG. 7 illustrates a cross-section view for fabricating the semiconductor device taken along the sectional line DD′ shown in FIG. 5, FIG. 9 illustrates a cross-section view for fabricating the semiconductor device taken along the sectional line EE′ shown in FIG. 8,, FIG. 10 illustrates a cross-section view for fabricating the semiconductor device taken along the sectional line FF′ shown in FIG. 8, and FIG. 11 illustrates a method for fabricating the semiconductor device following FIG. 10.

As shown in FIGS. 5 and 7, it would be desirable to follow the aforementioned process by first forming bases 20, 22 on the substrate 12 of the planar regions 14, 16 and fin-shaped structures 24 on the substrate 12 of the non-planar region 18, forming a patterned mask 26 on the planar regions 14, 16 and part of the fin-shaped structures 24 on the non-planar region 18, in which the patterned mask 26 includes an opening exposing part of the fin-shaped structures 24 on the non-planar region 18. Similar to the previous embodiment, the patterned mask 26 could be a multilayer mask made of an organic dielectric layer (ODL) 36, a silicon-containing hard mask bottom anti-reflective coating (SHB) 38, and a patterned resist 40.

Next, as shown in FIGS. 8-10, a fin cut process is conducted by using the patterned mask 26 as mask to remove part of the fin-shaped structures 24 on the non-planar region 18 and between the two planar regions 14, 16 through etching process. It should be noted that in contrast to the fin cut process conducted in the aforementioned embodiment of removing all the fin-shaped structures 24 on the non-planar region 18 and transforming all the remaining fin-shaped structures 24 into bumps, the present embodiment only removes part of the fin-shaped structures 24 on the non-planar region 18 by lowering the height of part of the fin-shaped structures 24 and turning these fin-shaped structures 24 into bumps 28, 30, 32, 42, 44.

In other words, as the patterned mask 24 is used to remove part of the fin-shaped structures 24 on the non-planar region 18, the patterned mask 24 is first disposed on the planar regions 14, 16 and part of the fin-shaped structures 24 on the non-planar region 18, and then an etching process is conducted by using the patterned mask 26 as mask to remove the fin-shaped structures 24 not covered by the patterned mask 24 so that the height of these uncovered fin-shaped structures 24 is lowered to form bumps with different heights. The remaining fin-shaped structures 24 (such as the ones between the bumps 28, 30, 32 shown in FIG. 8) not being etched then become dummy fin-shaped structures and the top surface of these dummy fin-shaped structures is preferably even with the top surface of the bases 20, 22 on the planar regions 14, 16. In contrast to transistor elements such as gate structures and source/drain regions are formed on the bases 20, 22 in the later process, no transistor elements is formed on the dummy fin-shaped structures on the non-planar region.

It should also be noted that since no bases are shown adjacent to two sides of the fin-shaped structures 24 in the cross-section view of FIG. 6 so that the patterned mask 26 adjacent to two sides of the fin-shaped structures 24 would have no height differences, the bumps 30, 42, 44 formed after removing part of the fin-shaped structures 24 as shown in FIG. 9 would then have same heights.

If viewed from the cross-section view of FIG. 7, similar to the embodiment shown in FIG. 2, since the a height difference is observed between the patterned mask 26 closer to the non-planar region 18 and the patterned mask 26 away from the non-planar region 18 such that the top surface of the patterned mask 26 closer to the non-planar region 18 is slightly lower than the top surface of the patterned mask 26 away from the non-planar region 18, after the etching process is conducted by using the patterned mask 26 to remove part of the fin-shaped structures 24 on the non-planar region 18 as shown in FIG. 10, the remaining fin-shaped structures 24 would be formed into bumps 28, 30, 32 having different heights on the substrate 12 of the non-planar region 18. Preferably, the quantity and heights of the bumps formed on the non-planar region 18 could vary according to the aforementioned embodiment and the details of which are not explained herein for the sake of brevity.

Next, as shown in FIG. 11, a shallow trench isolation (STI) 46 could be formed on the bumps 28, 30, 32 to surround the bases 20, 22, and a planar type transistor fabrication process could be carried out by forming gate structures 52 each made of a gate dielectric layer 48 and a gate electrode 50 on the bases 20, 22 respectively, a spacer 54 adjacent to each of the gate structures 52, and source/drain regions 56 in the bases 20, 22 adjacent to the spacers 54. Preferably, the STI 46 and the gate dielectric layer 48 could include silicon oxide, the gate electrode 50 could include polysilicon, the spacers 54 could include silicon oxide or silicon nitride, and the source/drain regions 56 could include n-type or p-type dopants depending on the type of transistor being fabricated. Since the fabrication of standard planar transistor is well known to those skilled in the art, the details of which is not explained herein for the sake of brevity.

Typically, during integration of planar type field effect transistors such as HV devices and/or MV devices and non-planar FETs such as LV devices, a plurality of dummy fin-shaped structures are disposed adjacent to or between planar regions for improving overall balance of the device. To allow the planar regions closer to each other by shrinking the require area of the entire chip, the present invention preferably removes all or part of the fin-shaped structures between planar regions during fin cut process so that the remaining fin-shaped structures would form bumps having uneven heights. According to a preferred embodiment of the present invention, the height of the bumps 28, 32 closer to the planar regions 14, 16 is slightly greater than the height of the bump 30 closer to the non-planar region 18, or more specifically the height of the bumps 28, 32 closer to the planar regions 14, 16 is greater than the height of the bump 30 in the middle or center of the non-planar region 18.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate having a first planar region and a non-planar region; and
bumps on the non-planar region, wherein the bumps comprise different heights.

2. The semiconductor device of claim 1, further comprising:
a second planar region adjacent to the first planar region, wherein the non-planar region is between the first planar region and the second planar region.

3. The semiconductor device of claim 2, further comprising:
a first base on the first planar region;
a second base on the second planar region; and
the bumps on the non-planar region.

4. The semiconductor device of claim 3, wherein top surfaces of the first base and the second base are coplanar.

5. The semiconductor device of claim 2, wherein a top surface of the bumps is lower than a top surface of the first base.

6. The semiconductor device of claim 2, wherein a top surface of the bumps is lower than a top surface of the second base.

7. The semiconductor device of claim 1, wherein a height of the bumps closer to the first planar region is greater than a height of the bumps closer to the non-planar region.

8. The semiconductor device of claim 1, wherein a height of the bumps closer to the first planar region is greater than a height of the bumps closer to a center of the non-planar region.

9. A semiconductor device, comprising:
a substrate having a planar region and a non-planar region;
bumps in the non-planar region; and
dummy fin-shaped structures in the non-planar region and adjacent to the bumps.

10. The semiconductor device of claim 9, further comprising:
a second planar region adjacent to the first planar region, wherein the non-planar region is between the first planar region and the second planar region.

11. The semiconductor device of claim 9, further comprising:
a first base on the first planar region;
a second base on the second planar region; and
the bumps and the dummy fin-shaped structures on the non-planar region.

12. The semiconductor device of claim 11, wherein top surfaces of the first base and the dummy fin-shaped structures are coplanar.

13. The semiconductor device of claim 11, wherein a top surface of the bumps is lower than a top surface of the first base.

14. The semiconductor device of claim 9, wherein a top surface of the bumps is lower than a top surface of the dummy fin-shaped structures.

15. The semiconductor device of claim 9, wherein the bumps comprise different heights.

16. The semiconductor device of claim 9, wherein a height of the bumps closer to the first planar region is greater than a height of the bumps closer to the non-planar region.

17. The semiconductor device of claim 9, wherein a height of the bumps closer to the first planar region is greater than a height of the bumps closer to a center of the non-planar region.
